(19) United States
(12) Patent Application Publication
(10) Pub. No.: US 2008/0308868 A1
(43) Pub. Date: Dec. 18, 2008

(54) HIGH VOLTAGE METAL OXIDE SEMICONDUCTOR TRANSISTOR AND FABRICATION METHOD THEREOF

(75) Inventors: Rong-Tzong Wu, Hsinchu City (TW); Guan-Quan Chen, Taichung City (TW); Hsin Tai, Taipei City (TW); Am-Tay Luy, Hsinchu County (TW); Pao-An Chang, Taoyuan County (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/763,911

(22) Filed: Jun. 15, 2007

(51) Int. Cl. H01L 23/62; H01L 21/336

(52) U.S. Cl. 257/355; 438/294; 257/E29.255; 257/E21.409

(57) ABSTRACT

A high voltage metal oxide semiconductor includes a doped substrate, two first isolation structures, a gate structure, a source region, a drain region, two second isolation structures, and two drift regions. The two first isolation structures are respectively disposed in the doped substrate. The gate structure is disposed between parts of the two first isolation structures on the doped substrate. The source region and the drain region are respectively disposed beside one side of each of the two first isolation structures in the doped substrate. The top surface of the second isolation structure is smaller than the bottom surface of the first isolation structure. The two drift regions are respectively disposed in the doped substrate, enclosing the source region and the drain region, the two first isolation structures and the second isolation structures.

### BACKGROUND OF THE INVENTION

1. Field of Invention

The present invention relates to an integrated circuit (IC) device and a fabricating method thereof. More specifically, the present invention is related to a high voltage metal oxide semiconductor.

2. Description of Related Art

In an IC device, it is essential that the different circuits having different fundamental operation characteristics are highly coordinated with each other. For example, a high voltage device is a device that can endure a higher bias voltage. In other words, the breakdown voltage of a high voltage device is higher than that of a general device.

Conventionally, a high voltage device is able to operate normally under a high voltage condition is by forming an isolation structure to enhance the junction breakdown voltage of the source/drain region. Although forming an isolation structure in the high voltage device raises the breakdown voltage, the required area of the device increases correspondingly. Hence, the conventional practice does not allow a further diminishment of the device dimension or an improvement of integration.

Accordingly, to fabricate an effective high voltage device without affecting the level of integration of the device is a serious issue to be resolved.

### SUMMARY OF THE INVENTION

The present invention is to provide a fabrication method of a high voltage metal oxide semiconductor transistor, wherein the breakdown voltage of the device is increased for the device to endure a high voltage operation.

The present invention is to provide a fabrication method of a high voltage metal oxide semiconductor transistor, wherein the breakdown voltage of the device is increased, while further diminishment of a device and an increase of integration are achieved.

The present invention is to provide a high voltage metal oxide semiconductor transistor, which includes a first type doped substrate, two first isolation structures, a gate structure, a second type source, a second type drain region, two second isolation structure and two second type drift regions. The two first isolation structures are respectively disposed in the first type doped substrate. The gate structure is disposed on the first type doped substrate between parts of the two first isolation structures. The gate structure includes a gate insulation layer and a gate. The second type source region and the second type drain region are respectively disposed one side of each of the two first isolation structures in the first type doped substrate. The two second isolation structures are respectively disposed under the two first isolation structures, wherein the top surface of the first isolation structure is smaller than the bottom surface of the second isolation structure. The two second type drift regions are respectively disposed in the first type doped substrate, enclosing the second type source region, the second type drain region, the two first isolation structures and the two second isolation structures.

According to a high voltage metal oxide semiconductor transistor of an embodiment of the invention, a material constituting the above-mentioned two first isolation structures includes a dielectric material or a doped dielectric material, for example.

According to a high voltage semiconductor metal oxide transistor of an embodiment of the invention, a material constituting the above-mentioned second isolation structure includes but not limited to a dielectric material or a doped dielectric material.

According to a high voltage metal oxide semiconductor transistor of an embodiment of the invention, the above mentioned first type doped substrate is doped with n-type dopants, for example, and the two second type drift regions, the second type source region and the second type drain region are doped with p-type dopants, for example.

According to a high voltage metal oxide semiconductor metal oxide transistor of an embodiment of the invention, the above mentioned first type doped substrate is doped with p-type dopants, for example, and the two second type drift regions, the second type source region and the second type drain region are doped with n-type dopants, for example.

According to a high voltage metal oxide semiconductor transistor of an embodiment of the invention, the above-mentioned two first isolation structures are shallow trench isolation structures or field oxide layers, for example.

According to a high voltage metal oxide semiconductor transistor of an embodiment of the invention, the above-mentioned first type doped substrate is a well region or an epitaxial layer, for example.

According to a high voltage metal oxide semiconductor transistor of an embodiment of the invention, wherein the transistor further includes two device isolation structures, respectively disposed at one side of each of the two second drift regions in the first type doped substrate.

The present invention further provides a fabrication method of a high voltage metal oxide semiconductor transistor. The method includes providing one first type doped substrate. Two isolation trench openings, including a first opening and a second opening configured at the bottom of the first opening, are then formed in the first type doped substrate, wherein the width of the top part of the second opening is smaller than the width of the bottom part of the first opening. Thereafter, the first opening and the second opening are filled with a dielectric layer or a doped dielectric layer to form respectively the first isolation structures and the second isolation structures, and to form respectively a second type drift region at a periphery of each of the two isolation structures. Thereafter, a gate structure is formed on the first type doped substrate between parts of the two first isolation structures. The gate structure includes a gate insulation layer and a gate. Hereafter, the second type source region and the second type drain region are respectively formed at one side of each of the two first isolation structures in the first type doped substrate.

According to a fabrication method of a high voltage metal oxide semiconductor transistor of an embodiment of the invention, the above mentioned first type doped substrate is doped with n-type dopants, for example, and the two second type drift regions, the second type source region and the second type drain region are doped with p-type dopants, for example.

According to a fabrication method of a high voltage metal oxide semiconductor transistor of an embodiment of the invention, the above mentioned first type doped substrate is doped with p-type dopants, for example, and the two second type drift regions, the second type source region and the second type drain region are doped with n-type dopants, for example.

According to a fabrication method of a high voltage metal oxide semiconductor transistor of an embodiment of the invention, the above-mentioned two first isolation structures are shallow trench isolation structures or field oxide layers, for example.

According to a fabrication method of a high voltage metal oxide semiconductor transistor of an embodiment of the invention, the above-mentioned first type doped substrate is a well region or an epitaxial layer, for example.

According to a fabrication method of a high voltage metal oxide semiconductor transistor of an embodiment of the invention, during the fabrication of the first opening and the fabrication of the first isolation structure in the first type doped substrate, a device isolation structure opening is also concurrently formed in the first type doped substrate and the device isolation structure opening is filled with a dielectric layer to form a device isolation structure.

Since under the first isolation structure of the high voltage metal oxide semiconductor transistor of the present invention, a second isolation structure is configured there-under as a current flow route, the high voltage semiconductor metal oxide transistor of the invention increases the current route to enhance the high breakdown voltage. Moreover, since the high breakdown voltage is enhanced by disposing another isolation structure under the first isolation structure, additional surface area of the device being occupied can be precluded. Accordingly, further diminishment of the dimension of the IC devices and an improvement of the level of integration are achieved.

In order to make the aforementioned and other objects, features and advantages of the present invention comprehensible, a preferred embodiment accompanied with figures is described in detail below.

### BRIEF DESCRIPTION OF THE DRAWINGS

FIG. 1 is a schematic, cross-section diagram of a high voltage metal oxide semiconductor transistor according to one embodiment of the invention.

FIGS. 2, 3A & 3B, 4 and 5 are schematic, cross-sectional views showing selected steps for the fabrication of a high voltage semiconductor transistor according to an embodiment of the present invention.

### DESCRIPTION OF EMBODIMENTS

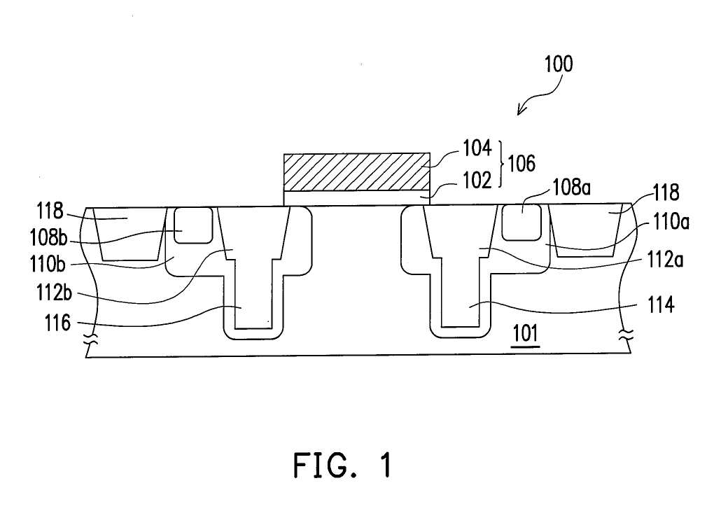

FIG. 1 is a schematic, cross-section diagram of a high voltage metal oxide semiconductor transistor according to one embodiment of the invention.

Referring to FIG. 1, the high voltage metal oxide semiconductor transistor 100 of an embodiment of the invention includes a first type doped substrate 101, a gate structure 106, a second type source region 108b and a second type drain region 108a, second type drift regions 110a and 110b, first isolation structures 112a and 112b, and second type isolation structures 114 and 116.

The first type doped substrate 101 includes a well region or an epitaxial layer, for example, and further includes two device isolation structures 118. The first isolation structures 112a and 112b are respectively disposed in the first type doped substrate 101, wherein the first isolation structures 112a and 112b are, for example, shallow trench isolation structure (STI). The first isolation structures 112a and 112b are constituted with a material including but not limited to a dielectric material or a doped dielectric material, wherein the dielectric material includes silicon oxide, for example.

The gate structure 106 is disposed over the first type doped substrate 101 between parts of the two first isolation structures 112a and 112b. The gate structure 106 mainly includes a gate insulation layer 102 and a gate 104. The gate insulation layer 102 is constituted with a material including but not limited to silicon oxide. The gate 104 is disposed on the gate insulation layer 102, wherein the gate 104 is formed with doped polysilicon, for example. It is important to note that the gate insulation layer 102 covers parts of the first isolation structures 112a and 112b to obviate the thinning problem of the gate insulation layer, in which the efficiency of the device may be adversely influenced.

Moreover, the second type drain region 108a and the second type source region 108b are respectively disposed in the first type doped substrate 101 on one side of each of the first isolation structures 112a and 112b.

The second isolation structure 114 is disposed under the first isolation structure 112a, wherein the top surface of the second isolation structure 114 is smaller than the bottom surface of the first isolation structure 112a. Moreover, the second isolation structure 116 is disposed under the first isolation structure 112b, wherein the top surface of the second isolation structure 116 is smaller than the bottom surface of the first isolation structure 112b. The material constituting the second isolation structure 114 can be the same or a different material than that constituting the first isolation structures 112a and 112b, for example a dielectric material or a doped dielectric material, wherein the dielectric material includes silicon oxide, for example.

Moreover, the two second type drift regions 110a and 110b are disposed in the first type doped substrate 101, enclosing the second type drain region 108a and the second type source region 108b, the first isolation structures 112a and 112b, and the second isolation structures 114 and 116.

In the above embodiment, the first isolation structures 112a and 112b are, for example, shallow trench isolation structures. In another embodiment, the first isolation structure 112a and 112b are, for example, field oxide layers, for example.

If the above-mentioned high voltage metal oxide semiconductor transistor 100 is a p-type high voltage metal oxide semiconductor transistor, the first type doped substrate is n-type, the second type drift regions 110a and 110b and the second type drain regions 108a and the second type source region 108b are p-type. Further the first isolation structures 112a and 112b and the second isolation structures 114 and 116 are included with a doped dielectric material, such as boron silicate glass (BSG). On the other hand, if the above-mentioned high voltage metal oxide semiconductor transistor 100 is an n-type high voltage metal oxide semiconductor transistor, the first type doped substrate is p-type, the second type drift regions 110a and 110b and the second type drain region 108a and the second type source region 108b are n-type. Further the first isolation structures 112a and 112b and the second isolation structure 114 are included with a doped dielectric material, such as phosphorous silicate glass (PSG) or arsenic silicate glass (ASG).

According to the above embodiments, the high voltage metal oxide semiconductor transistor of the present invention includes a second isolation structure configured under the first isolation structure. Further, the peripheral region of the second isolation structure serves as a flow route for the current. Ultimately, the high voltage metal oxide semiconductor transistor of the invention provides an increase of the current route to enhance the break-down voltage. Moreover, the high voltage metal oxide semiconductor transistor of the invention does not rely on the conventional approach of expanding laterally the dimension of the isolation structure. Instead, the increase of the high breakdown voltage of the high voltage metal oxide semiconductor transistor of the present invention is accomplished by disposing another isolation structure under the first isolation structure. As a result, not only the device dimension is obviated from being increased, further diminishing the dimension of an IC device is accomplished and the level of integration is improved:

Moreover, the high electric field that may potentially occur at the corner of the first isolation structure of the high voltage metal oxide semiconductor transistor may move to the corner of the second isolations structure. The above approach of lowering the surface electric field may also raise the high break-down voltage effectively.

In another embodiment, the high voltage metal oxide semiconductor transistor of the invention further includes disposing a first isolation structure and a second isolation structure (not shown) at the drain side to increase the current flow route and the raise the break-down voltage. Further, occupation of additional area by the device can be precluded. Accordingly, further diminishment of the dimension of the IC devices and an improvement of the level of integration are achieved.

The fabrication method of a high voltage metal oxide semiconductor transistor of the invention shown in FIG. 1 now will be described more fully hereinafter by way of the following embodiments.

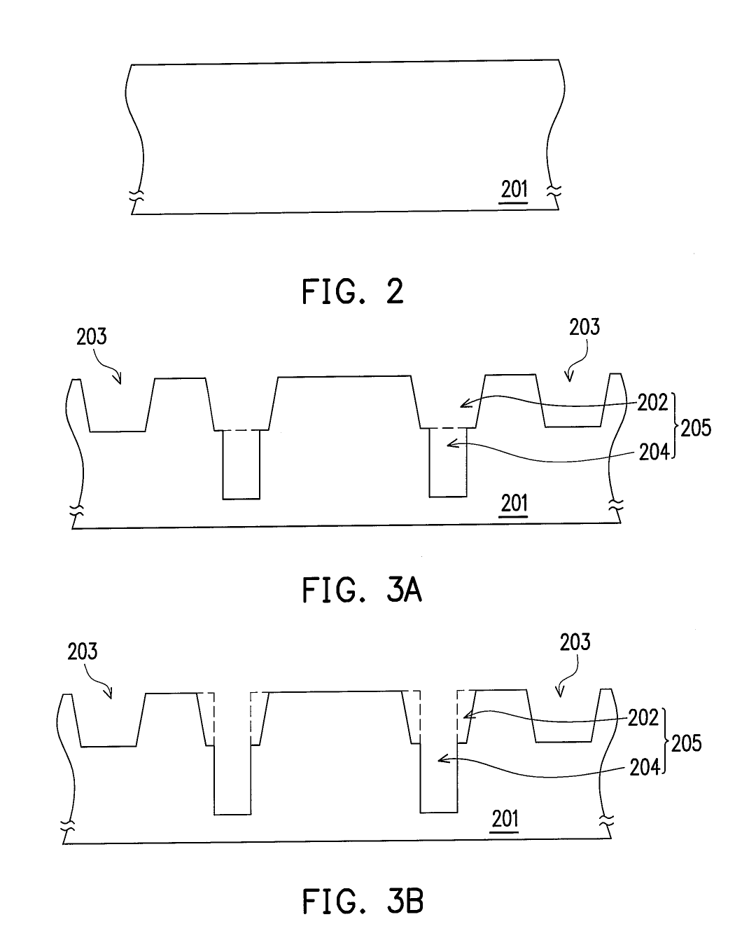

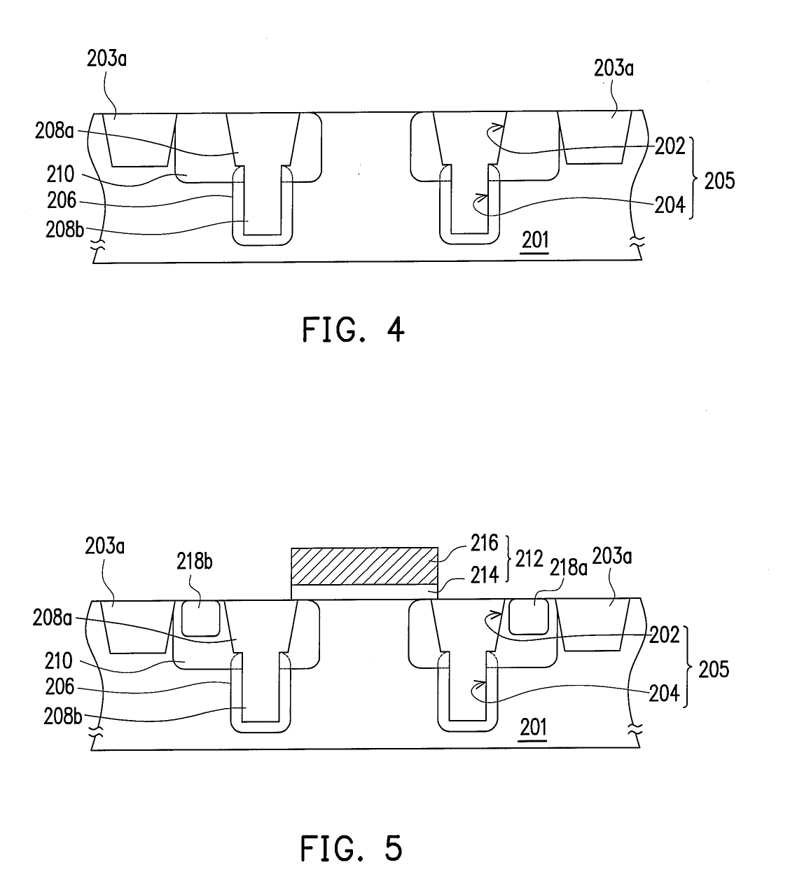

FIGS. 2, 3A & 34B, 4 and 5 are schematic, cross-sectional views showing selected steps for the fabrication of a high voltage semiconductor transistor according to an embodiment of the present invention.

Referring to FIG. 2, a first type doped substrate 201 is provided. In this embodiment, the first type doped substrate 201 is, for example, n-type doped substrate. The first type doped substrate 210 includes but not limited to an n-type well region, formed by, for example, performing an ion implantation process using phosphorous as dopants. In another example, the first type doped substrate is, for example, n-type epitaxial layer. The n-type epitaxial layer is formed by, for example, performing a chemical vapor deposition process with in-situ doping, using phosphorus as dopants, followed by performing a solid phase epitaxy process. More particularly, the subsequent ion implantation process may be eliminated to lower the manufacturing cost by using the epitaxial layer as the first type doped substrate.

Reference now is made to FIGS. 3A and 3B to describe the various embodiments and examples of the fabrication of the two isolation trench openings. Wherever possible, the same reference numbers are used in the drawings and the description to refer to the same or like parts. As shown in FIGS. 4A and 4B, two isolation trench openings 205 and a device isolation structure opening 203 are formed in the first type doped substrate 201. Each of the two isolation trench openings 205 includes a first opening 202, and at the bottom of the first openings 202 further includes a second opening 204. Moreover, the width of the top part of the second opening 204 is smaller than the width of the bottom part of the first opening 202.

Referring to FIG. 3A, two first openings 202 are formed in the first type doped substrate 201. The first openings 202 are formed by, for example, forming a patterned mask (not shown) over the first type doped substrate 201, followed by performing an etching process to remove portions of the first type doped substrate 201 using the patterned mask as an etching mask. Thereafter, second openings 204 are formed in the first type doped substrate 201 at the bottom of the first openings 202. The width of the top part of each second opening 204 is smaller than the width of the bottom part of each first opening 202. The second opening 204 is formed by performing an etching process, for example. In this embodiment, two second openings 204 are formed under the two first openings 202. Further, during the fabrication of the first openings 202, a device isolation structure opening 203 may form concurrently.

Referring to FIG. 3B, alternatively, the two isolation structure openings 205 are formed by, for example, forming the second openings 204 in the first type doped substrate 201, followed by removing a portion of the first type doped substrate 201 at the peripheral of the upper half of the second openings 204 to form the first openings 202. Further, during the fabrication of the first openings 202, a device isolation structure opening 203 may form concurrently.

After forming the isolation structure openings 205 and the device isolation structure opening 203, the fabrication of the isolation structures and the drift regions is continued as described in the following FIG. 4.

As shown in FIG. 4, a dielectric layer or a doped dielectric layer is formed filling the second openings 204 and the first openings 202 to respectively form the isolation structures 208b and 208a. The above-mentioned dielectric layer is, for example, a silicon oxide layer, and the above-mentioned doped dielectric layer is, for example, boron silicate glass. Further, during the fabrication of the first openings 202, a device isolation structure opening 203 may form concurrently. A drift region 210 is formed in the first type doped substrate 201 at the peripheral of the isolation structure 208a. Further, a drift region 206 is formed at a sidewall and a bottom of the second opening 204 in the first type doped substrate 201. The drift regions 210 and 206 may form by performing an ion implantation process using p-type dopants, for example. The drift regions 210 and 260 may also formed by performing a thermal process to induce diffusion of the dopants in the doped dielectric layer that fills the openings.

In accordance to the above embodiment, the device isolation structure 203a and the isolation structures 208a are concurrently formed. Further, the isolation structures 208a and 208b and the drift regions 210 and 206 may fabricate according to the following various methods. However, the present invention should not be construed as limited to the embodiments set forth herein. In another embodiment, the isolation structures 208a are formed by, for example, filling a silicon oxide layer in the first openings 202. The isolation structures 208b are formed by filling boron-silicate glass in the second openings 204, for example. The drift region 210 is formed by, for example, performing an ion implantation process, while the drift region 206 is formed by performing a thermal process to induce diffusion of the dopants in the boron silicate glass to the first type doped substrate 201.

In another embodiment, the isolation structures 208a and 208b, for example, are formed by filling a silicon oxide layer in the first openings 202 and the second openings 204, while the drift regions 206 and 210 are formed by, for example, an ion implantation process.

In yet another embodiment, the isolation structures 208a and 208b are formed by, for example, filling the first openings 202 and the second openings 204 with a boron silicate glass layer, for example. The drift region 210 is fabricated by applying a thermal process, for example, to induce the dopants in the boron silicate glass layer in the isolation structure 208b to diffuse into the first type doped substrate, while the drift region 206 is fabricated by an ion implantation method.

Subsequent to the formation of the isolation structures 208a and 208b, the device isolation structure 203a and the drift regions 206 and 210, a gate structure 212 is formed between parts of the isolation structures 208a and 208b in the first type doped substrate 201, as shown in FIG. 5. The gate structure 212 is mainly formed with a gate insulation layer 214 and a gate 216. The method of forming the gate insulation layer is well known to skilled artisans, and thus it will not be further iterated. The drain region 218a and the source region 218b are respectively formed in the first doped substrate 210 beside one side of each of the isolation structures 208a and 208b. The drain region 218a and the source region 218b are formed by, for example, performing an ion implantation process, using p-type dopants.

It is further worthy to note that the first type doped substrate 201 also includes device isolation structure (not shown) formed therein, beside one side of the drift regions 206 and 210. The above device isolation structure is formed by, for example, forming a device isolation structure opening during the formation of the first opening 202, followed by filling a dielectric layer in the device isolation structure opening.

Although the disclosure herein refers to certain illustrated embodiments of a p-type high voltage semiconductor transistor, it is to be understood that these embodiments are presented by way of example and not by way of limitation. For example, it is understood by a person of ordinary skill practicing this invention that if the above-mentioned high voltage metal oxide semiconductor transistor is an n-type high voltage metal oxide semiconductor transistor, the first type doped substrate 201 is p-type, the drift regions 206 and 210 and the drain region 218a and the source region 218b are n-type, and the isolation structures 208a and 208b are filled with a doped dielectric layer, such as a phosphorous silicate glass layer or an arsenic silicate glass layer.

In accordance to the above disclosure, the high voltage metal oxide semiconductor transistor of the present invention provides at least the following advantages.

The high voltage metal oxide semiconductor transistor of the present invention increases the current route to raise the high breakdown voltage.

The high voltage metal oxide semiconductor transistor of the present invention lowers the surface electric field, which can also effectively raise the high breakdown voltage.

According to the high voltage metal oxide semiconductor transistor of the present invention, not only the high breakdown voltage is enhanced, further diminishing the dimension of an IC device is achieved and the level of integration is improved.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A high voltage metal oxide semiconductor transistor, comprising:
a first type doped substrate;
two first isolation structures, respectively disposed in the first type doped substrate;
a gate structure, disposed between parts of the two first isolation structures on the first type doped substrate, wherein the gate structure includes a gate insulation layer and a gate;
one second type source region and one second type drain region, respectively disposed in the first type doped substrate beside one side of each of the two first isolation structures;
two second isolation structures, respectively disposed under the two first isolation structures, wherein a top surface of the second isolation structure is smaller than a bottom surface of the one of the first isolation structures; and
two second type drift regions, respectively disposed in the first type doped substrate, enclosing the second type source region and the second type drain region, the two first isolation structures and the second isolation structure.

2. The high voltage metal oxide semiconductor transistor of claim 1, wherein a material constituting the two first isolation structures comprises a dielectric material or a doped dielectric material.

3. The high voltage metal oxide semiconductor transistor of claim 1, wherein a material constituting the two second isolation structure comprises a dielectric material or a doped dielectric material.

4. The high voltage metal oxide semiconductor transistor of claim 1, wherein the first type doped substrate comprises n-type dopants, and the two second type drift regions, the second type doped source region and the second type doped drain region comprise p-type dopants.

5. The high voltage metal oxide semiconductor transistor of claim 1, wherein the first type doped substrate includes p-type dopants, and the two second type drift regions and the second type doped source region and the second type doped drain region comprise n-type dopants.

6. The high voltage metal oxide semiconductor transistor of claim 1, wherein the two first isolation structures are shallow trench isolation structures or field oxide layers.

7. The high voltage metal oxide semiconductor transistor of claim 1, wherein the first type doped substrate is a well region or an epitaxial layer.

8. The high voltage metal oxide semiconductor transistor of claim 1 further comprising two device isolation structures respectively disposed at one side of each of the two second type drift regions in the first type doped substrate.

9. A method for fabricating a high voltage metal oxide semiconductor transistor, the method comprising:
providing a first type doped substrate;
forming two isolation structure openings in the first type doped substrate, wherein each of the two isolation structure openings comprises one first opening and one second opening formed under the first opening, wherein a width of a top part of the second opening is smaller than a width of a bottom part of the first opening;
forming a dielectric layer or a doped dielectric layer in the first openings and the second openings to form respectively two first isolation structures and two second isolation structures, and respectively forming a second type drift region at a peripheral of each of the two isolation structure openings;
forming a gate structure between parts of the two first isolation structures on the first type doped substrate, wherein the gate structure comprises a gate insulation layer and a gate; and
forming a second type source region and a second type drain region respectively beside one side of each of the two first isolation structures in the first type doped substrate.

10. The method according to claim 9, wherein the first type doped substrate is doped with n-type dopants, and the two second type drift regions and the second type source region and the second type drain region are doped with p-type dopants.

11. The method according to claim 9, wherein the first type doped substrate is doped with p-type dopants, and the two second type drift regions and the second type source region and the second type drain region are doped with n-type dopants.

12. The method of claim 9, wherein the two first isolation structures are shallow trench isolation structures or field oxide layers.

13. The method of claim 9, wherein the first type doped substrate is a well region or an epitaxial layer.

14. The method of claim 9, wherein during the step of forming the first opening and the step of forming the first isolation structure in the first type doped substrate, a device isolation structure opening is concurrently formed in the first type doped substrate, and filling a dielectric layer in the device isolation structure opening to form a device isolation structure.
